(19) United States
(12) Patent Application Publication
(10) Pub. No.: US 2024/0136372 A1
(43) Pub. Date: Apr. 25, 2024

(54) PINNED PHOTODIODE PIXEL

(71) Applicant: ams-OSRAM Asia Pacific Pte. Ltd., Singapore (SG)

(72) Inventors: Benjamin Joseph SHEAHAN, Eindhoven (NL); Jong Mun PARK, Eindhoven (NL); Robert VAN ZEELAND, Eindhoven (NL); Kirk David PETERSON, Eindhoven (NL); Wern Ming KOE, Eindhoven (NL); George Richard KELLY, Eindhoven (NL); Mario MANNINGER, Eindhoven (NL); Dong-Long LIN, Eindhoven (NL); Pascale FRANCIS, Eindhoven (NL); Koen RUYTHOOREN, Eindhoven (NL)

(21) Appl. No.: 18/278,500

(22) PCT Filed: Feb. 22, 2022
(86) PCT No.: PCT/SG2022/050084

§ 371 Date: Aug. 22, 2023

Related U.S. Application Data
(60) Provisional application No. 63/152,926, filed on Feb. 24, 2021.

(30) Foreign Application Priority Data
Oct. 7, 2021 (GB) 2114445.6

(51) Int. Cl. H01L 27/146

(52) U.S. Cl. CPC H01L 27/1461; H01L 27/14645

(57) ABSTRACT

A pixel for an ambient light and/or color sensor includes a plurality of pinned photodiodes. The pixel also includes a floating diffusion region. A ratio of an active area of the plurality of pinned photodiodes to an area of the floating diffusion region is greater than 150.

### FIELD OF DISCLOSURE

The present disclosure is in the field of ambient light and color sensing, and in particular relates to pixels for ambient light and color sensors implemented with pinned photodiodes.

### BACKGROUND

Radiation sensors are commonly used in electronic devices such as smartphones, smart-watches, tablet devices and laptop computers. Such devices typically have displays, e.g. LED screens, for presenting information to a user. Furthermore, such electronic devices may also comprise image-sensing devices, such as cameras.

An effectiveness of displays in presenting information to a user may be influenced by ambient radiation. For example, in bright environments characterized by a high intensity of ambient radiation, it may be desirable to increase a brightness of the display to increase an overall perceptibility of displayed information. Conversely, in low light environments characterized by a low intensity of ambient radiation, it may be desirable to decrease a brightness of the display to avoid irritation to a user's eyes.

Similarly, an ability for a device to capture an image and/or display a captured image may also be affected by ambient radiation levels. In particular, a color of ambient radiation may affect an ability of an image-sensing device to perform white-balancing of an image.

Radiation sensors may provide detailed information about an ambient radiation level. For example, one or more radiation sensors may generally be implemented on such electronic devices to enable the device to adapt a brightness of a display in response to a detected ambient radiation level. However, existing radiation sensors may exhibit a limited dynamic range, thus limiting their suitability for accurately sensing ambient radiation levels across a wide range of lighting conditions, e.g. ranging from strong direct sunlight to low-light conditions.

Radiation sensors may also provide information about a color of incident radiation. Information about the color of incident radiation may enabled features such as auto-white-balancing (AWB) of images captured by a camera and/or adjustment of a display of images in response to a sensed color and/or intensity of ambient radiation. Furthermore, information about the color of incident radiation may enable classification of an ambient radiation source.

Sensing of ambient radiation may be known in the art as Ambient Light Sensing (ALS). In the context of ambient radiation, the term ‘light’ will be understood to encompass visible and/or non-visible radiation, e.g. infrared and/or ultraviolet radiation. A requirement of ALS is to detect ambient radiation intensity levels and/or colors with a relatively high degree of accuracy. Existing radiation sensors may be limited in their ability to distinguish between different colors of incident radiation.

A recent trend in portable device design, and in particular in the design of smartphones, is to maximize a display area by reducing an area of a bezel. This may be achieved, at least in part, by positioning sensors such as radiation sensors behind the display.

By mounting a sensor behind a display, an intensity of radiation incident upon the sensor may be reduced due to a degree of opacity of the display. Furthermore, in some instances the display itself may emit radiation that may interfere with measurements of radiation by sensors disposed behind the display.

It is therefore desirable to provide a sensor suitable for disposal behind a display of a portable device that exhibits a high level of optical sensitivity with high accuracy, while also being characterized by a relatively low ‘dark-count’, e.g. a low signal level in the absence of incident radiation.

Furthermore, it is also desirable to provide a sensor exhibiting a wide dynamic range suitable for use across a full range of ambient radiation conditions, such as direct sunlight and low-light conditions.

Requirements in low-power, performance and miniaturization have also driven a necessity for a high degree of integration of components in such electronic devices. With such integration and miniaturization, a susceptibility of sensors to the effects of noise, and in particular power-supply noise, may be increased. It is therefore also desirable to provide a highly integratable sensor exhibiting a high degree of immunity to noise, and in particular having a high Power-Supply-Rejection-Ration (PSRR).

It is therefore an aim of at least one embodiment of at least one aspect of the present disclosure to obviate or at least mitigate at least one of the above identified shortcomings of the prior art.

### SUMMARY

The present disclosure is in the field of ambient light and color sensing, and in particular relates to pixels for ambient light and color sensors implemented with pinned photodiodes.

According to a first aspect of the disclosure, there is provided a pixel for an ambient light and/or color sensor. The pixel comprises a plurality of pinned photodiodes and a floating diffusion region. A ratio of an active area of the plurality of pinned photodiodes to an area of the floating diffusion region is greater than 150.

Advantageously, instead of using large n-well based photodiodes or even island photodiodes, as conventional ambient light sensors may do, the present disclosure relates to a pixel implementation that uses pinned photodiodes to achieve high sensitivity yet low noise measurements of a color and/or intensity of incident radiation.

Advantageously, the use of pinned photodiodes enables adaptation of a technology normally associated with image sensors and readily manufactured in a low-voltage CMOS compatible process.

Advantageously, the use of pinned photodiodes enables extremely fast sensing of incident radiation, relative to sensing radiation with a conventional n-well ‘slab’ photodiode.

Advantageously, having a relatively large active area of the plurality of pinned photodiodes relative to an area of the floating diffusion region may improve an overall optical sensitivity and gain of the pinned photodiodes. In particular, a relatively small area of the floating diffusion region may reduce a capacitance of the floating diffusion region, and hence increase a sensitivity of the pixel.

Advantageously, the disclosed pixel is suited for high sensitivity and high dynamic range applications, because the disclosed pixel exhibits advantages associated with both small and large pixel designs. By implementing dynamic timing switching and high pixel conversion gains, the disclosed pixel can be implemented in sensors providing relatively high Signal-to-Noise Ratio (SNR) data.

An active area of each pinned photodiode of the plurality of pinned photodiodes may be at least 25 μm².

In an example embodiment, each pinned photodiode may have dimensions in the region of 10 μm×10 μm. In some embodiments, a total area of each pinned photodiode may be in the region of 12 μm×12 μm, resulting in a highly sensitive yet scalable architecture.

An active area may be defined as an area within each pinned photodiode that is diffused to create a P-N or N-P junction for converting photons into an electrical current.

The floating diffusion region may be configured to have a capacitance of 2.5 Femtofarads or less.

Advantageously, such a low capacitance in combination with relatively short integration times may provide a relatively high conversion gain. For example, in some embodiments, a conversion gain of 80 μV/e− or greater may be achieved.

The pixel may be an active pixel. For example, the pixel may comprise one or more transistors, e.g. MOSFETs, for controlling operation of the pixel.

The pixel may comprise a reset transistor configured to reset the floating diffusion to a reference voltage.

In an example, a threshold voltage of the reset transistor may be configured to be greater than 0.1V.

That is, a threshold of the reset transistor may be relatively high when compared to a pixel implemented in a regular CMOS image sensor. In some embodiments, the threshold may be implemented using a high-threshold implant, adjusted to provide a lower-leakage transistor compared to that of a regular CMOS image sensor.

Advantageously, a threshold of greater than 0.1 volts enables a reduction in leakage currents, thereby reducing a dark count. The reset transistor may be sized to minimize any parasitic capacitances.

The pixel may comprise a plurality of transfer gates. Each transfer gate may be configurable to transfer a charge from one of the plurality of pinned photodiodes to the floating diffusion.

The pixel may comprise a read-out transistor. The read-out transistor may be configured as a source-follower transistor for sampling a voltage at the floating diffusion.

The read-out transistor may be relatively small, thus minimizing the effects of any parasitic gate capacitance of the read-out transistor contributing to an overall capacitance of the floating diffusion. Dimensions of the read-out transistor may be selected to trade off sensitivity and noise.

The read-out transistor may be formed having a gate width of less than 1 μm.

In some examples, a relatively narrow-width read-out transistor may be implemented, wherein a gate width may be 1 μm or even narrower. The read-out transistor may be implemented using dedicated implants to reduce the channel random trap and to adjust a threshold voltage (Vₜₕ) of the device.

Signals for controlling each transfer gate and/or reset transistor, and/or any metal lines for shielding such signals, may be routed at a minimum distance of at least 1 μm from the floating diffusion region.

Advantageously, by avoiding routing signals near to the floating diffusion region, noise and interference may be reduced. This may be particularly important for color sensing applications, due to increased sensitivity requirements and need to reduce dark count relative to regular CMOS image sensors.

A total thickness of the substrate and the pixel may, for example, be in a range of around 2 to 6 μm, depending upon process capability.

A total thickness of the substrate and pixel may be increased by increasing a thickness of an epi-layer.

Advantageously, by increasing the total thickness a temperature coefficient of red response may be reduced. While a total thickness, e.g. the epi-thickness, may not be particularly important for pixels for regular CMOS image sensors, such an increased thickness makes the disclosed pixel particularly suited to color sensing applications by improving a red-response.

In some examples, color sensors and/or ambient light sensors implemented using the disclosed pixel may sensor color by determining a ratio of sensed red radiation to sensed green and/or blue radiation, and thus for accurate color sensing a stability of sensed color across an operating temperature range is advantageous.

The pixel may comprise four pinned photodiodes arranged around the floating diffusion region.

The four pinned photodiodes may be arranged in a grid or array, with the floating diffusion region disposed substantially towards a central region of the pixel.

According to a second aspect of the disclosure, there is provided a sensor for color or ambient light sensing. The sensor comprises at least one pixel according to the first aspect.

The sensor may comprise a plurality of pixels. The circuitry may be configured to average a signal from each pixel of the plurality of pixels prior to analog-to-digital conversion.

For example, in some embodiments, the sensor may comprise a plurality of pixels arranged in arrays. Advantageously, use of pinned photodiodes arranged in pixels provides a scalable architecture, and therefore is particularly suited to implementations of multi-channel sensors.

Advantageously, averaging the signals from a plurality of pixels may result in reduced noise.

In some embodiments, averaging of a signal from each of the pixels may be performed by the circuitry in the digital domain. Furthermore, it will be understood that, in addition to or as an alternative to averaging, filtering such as filtering with an FIR filter, may be performed on the signals from a plurality of pixels.

The sensor may comprise circuitry configurable to selectively couple each pinned photodiode to the floating diffusion region.

The circuitry may be configurable to select an integration time and to couple one or more of the plurality of pinned photodiodes to the floating diffusion region in response to a sensed intensity of radiation incident on the pixel.

Ambient light sensing applications may have more stringent requirements for high dynamic range and high linearity than image sensor applications. Advantageously, the disclosed sensor may overcome the shortcomings of the prior art by adapting both the integration time and an amount of photodiodes coupled to the floating diffusion region in response to a sensed intensity of radiation incident on the pixel, thereby ensuring that the pinned photodiodes sense radiation within an optimal range of operation of the pinned photodiodes. Thus, the pinned photodiodes in the disclosed sensor may achieve a sufficient dynamic range and linearity of response for ambient light and/or color sensing applications.

For example, in low incident radiation intensity conditions, the circuitry may be configured to couple a relatively large amount, e.g. a maximum amount, of pinned photodiodes to the floating diffusion. Conversely, in high incident radiation intensity conditions, the circuitry may be configured to couple a relatively low amount, e.g. a minimum amount, of pinned photodiodes to the floating diffusion. Similarly, an integration time may be reduced in high incident radiation intensity conditions or increased in low incident radiation intensity conditions to ensure the pinned photodiodes operate within an optimal range, as described in more detail below.

The sensor may be configured to exhibit a resolution of at least 12 bits and/or a dynamic range of at least 22 bits.

Advantageously, by implementing the sensor with pinned photodiodes, and by overcoming the shortcomings of limited dynamic range and non-linearity that may otherwise be associated with pinned photodiodes as described above, e.g. with large area, short integration times, low capacitance and thus high conversion gain, the sensor is suitable for use in ambient light and/or color sensing applications with adequate resolution and dynamic range

According to a third aspect of the disclosure, there is provided an electronic device comprising the sensor according to the second aspect, wherein the sensor is configured for backside-illumination.

The electronic device may be a smartphone, tablet device, smart-watch, a laptop device, a personal computer, a camera, or a television. The device may be configured to receive and/or transmit a signal.

That is, the sensor may be arranged within the electronic device such that radiation to be sensed is incident on a backside of the sensor. As such, in some embodiments, the radiation to be sensed may propagate through a substrate on which the sensor is formed.

Advantageously, by making use of backside illumination, enhanced sensitivity may be achieved while avoiding optical losses, especially at wavelengths of approximately 425 nanometers, e.g. blue light, due to nitride isolation layers implemented in advanced CMOS metal systems.

The sensor may comprise an LED display. The sensor may be disposed rearward of a radiation-emitting surface of the LED display and configured and receive radiation propagating through the LED display.

Advantageously, the sensor may be suitable for use in Behind-OLED (BOLED) applications In some embodiments, operation of the sensor may be synchronized with the LED display. For example, the sensor may be configured to sense radiation propagating through the LED display without interference from radiation emitted by the LED display.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE PREFERRED EMBODIMENTS

These and other aspects of the present disclosure will now be described, by way of example only, with reference to the accompanying drawings, wherein:

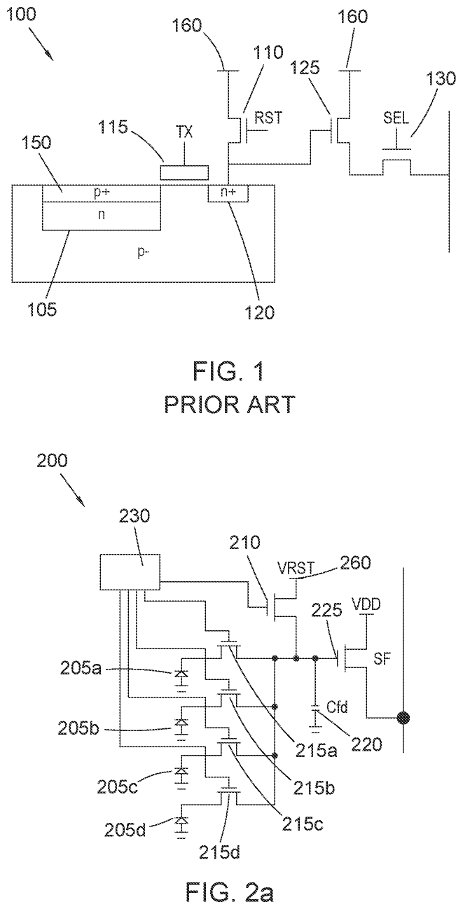

FIG. 1 depicts a representation of a prior art four transistor (4T) pinned photodiode pixel;

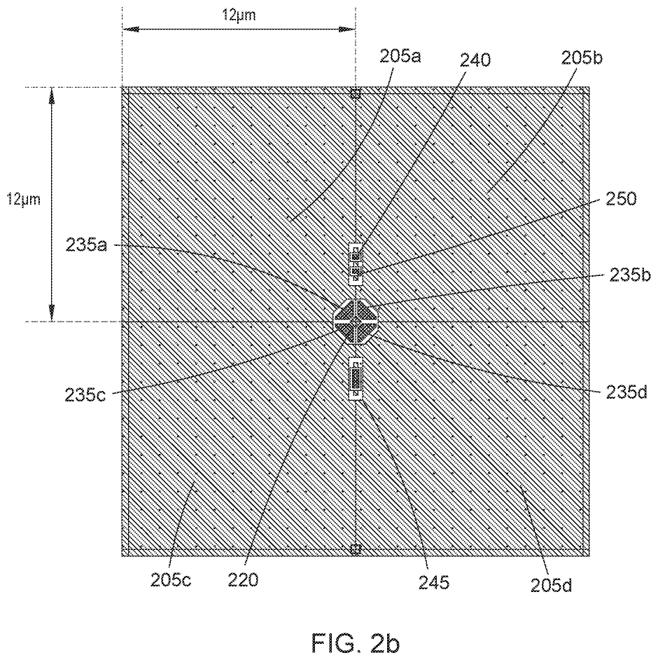

FIG. 2a depicts a schematic diagram of a pixel according to an embodiment of the present disclosure;

FIG. 2b depicts a plan view of a pixel according to an embodiment of the present disclosure;

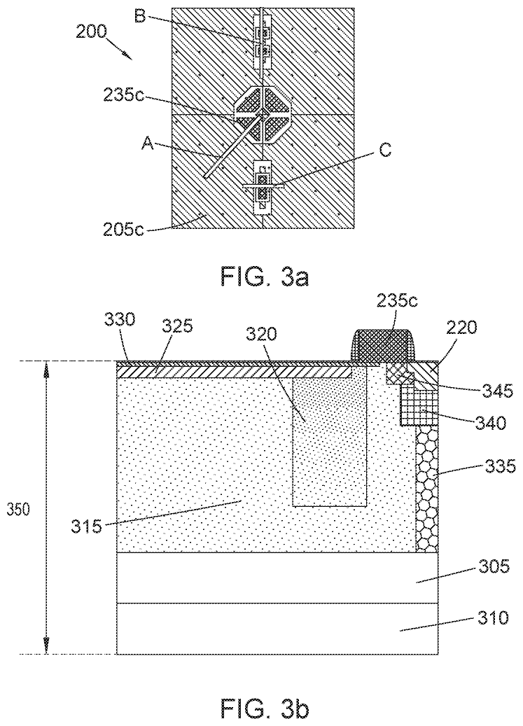

FIG. 3a depicts a portion of the pixel of FIG. 2b;

FIG. 3b depicts a cross section of the portion of the pixel in FIG. 3a along a line marked “A”;

FIG. 3c depicts a cross section of the portion of the pixel in FIG. 3a along a line marked “B”;

FIG. 3d depicts a cross section of the portion of the pixel in FIG. 3a along a line marked “C”;

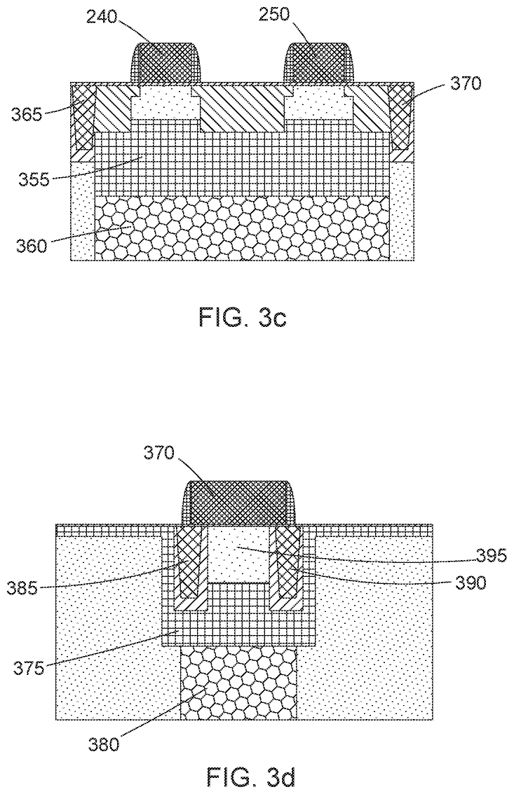

FIG. 4 depicts a representation of a plan view of a pixel showing signals routed over the pinned photodiodes;

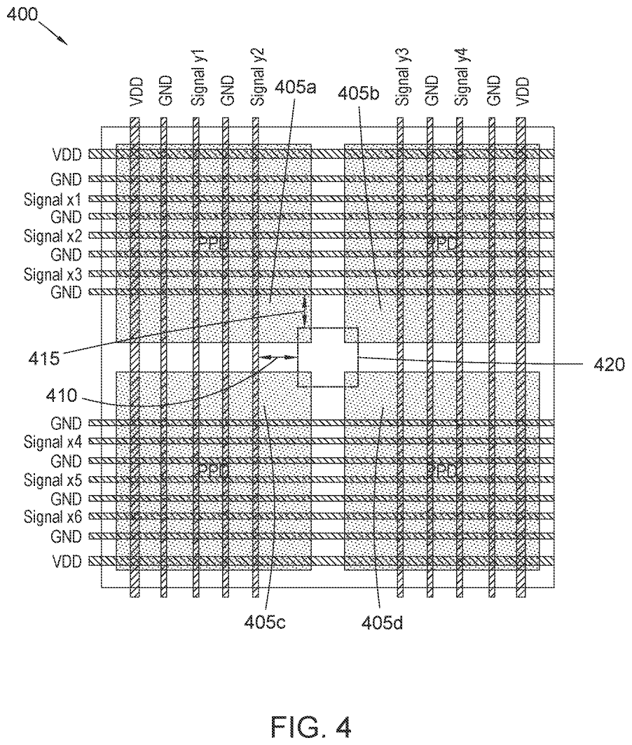

FIG. 5 depicts a circuit diagram representing a portion of a sensor according to an embodiment of the disclosure; and

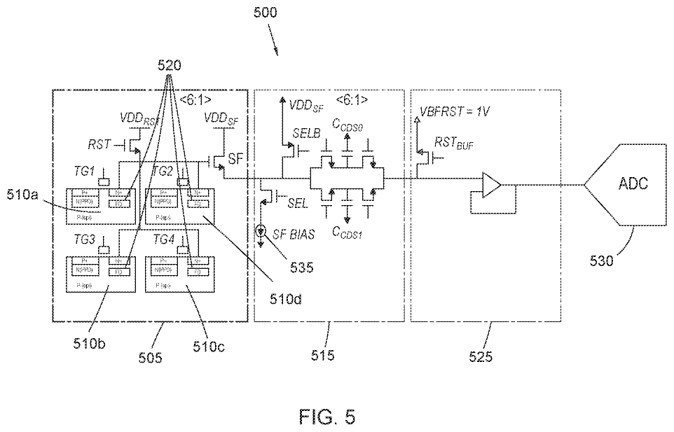

FIG. 6 an electronic device according to an embodiment of the disclosure.

### DETAILED DESCRIPTION

FIG. 1 depicts a representation of a prior art four transistor (4T) active pixel, generally denoted 100, as may commonly be implemented in an image sensor. The active pixel 100 comprises a photodiode 105, a reset transistor 110, a transfer transistor 115, a source-follower transistor 125, and a row select transistor 130.

For purposes of example, a CMOS structure of the photodiode 105 and the transfer transistor 115 are depicted. For simplicity, the reset transistor 110, the source-follower transistor 125 and the row select transistor 130 are shown as symbolic representations of transistors.

The photodiode 105 comprises a p-n junction diode configured to be exposed to radiation and to convert incident radiation into a voltage signal though a process of optical absorption. The principles of generation of electron-hole pairs by optical absorption are well known, and will not be described here for reasons of expediency.

The photodiode 105 in active pixel 100 is a pinned photodiode. That is, the photodiode 105 has been passivated with a shallow p+ implant, known as a pinning layer, above a radiation-sensitive structure of the photodiode 105. The pinning layer 150 permits a total transfer of charge onto an n+ floating diffusion region 120 under the control of the transfer transistor 115, as will be described below. Again, pinned photodiodes are well known in the art and will not be further described at this juncture.

The transfer transistor 115 comprises the floating diffusion region 120. The transfer transistor 115 is configured to move a charge from the photodiode 105 to the floating diffusion region 120.

The reset transistor 110 is coupled between the voltage reference 160 and the floating diffusion region 120 to reset the active pixel 100, e.g., discharge or charge the floating diffusion region 120 and the photodiode 105 to a reset voltage under control of the reset transistor 110.

The source-follower transistor 125 is operated effectively as a voltage buffer. An input voltage, e.g. a voltage at a gate of the source-follower transistor 125, corresponds to a voltage of the floating diffusion region 120. An output of the source-follower transistor 125, e.g. the source terminal of the source-follower transistor 125, generally corresponds to the voltage at the gate of the source-follower transistor 125, minus a voltage dropped across the source follower transistor 125. Beneficially, the source-follower transistor 125 does not draw a substantial current from the floating diffusion region 120, thus allowing a measurement of a voltage at the floating diffusion region 120 without discharging the floating diffusion region 120.

The row select transistor 130 selectively couples the voltage at the source of the source-follower transistor 125 to a further circuit, typically comprising measurement circuitry such as an ADC, to measure the effective voltage at the floating diffusion region 120. In use, the voltage at the floating diffusion region 120 corresponds to a charge stored at the floating diffusion region 120, and thus is indicative of an intensity of light which the photodiode has been exposed to over an integration time.

A typical mode of operation of the prior art 4T active pixel 100 is as follows.

In an initial stage of operation, a reset signal RST is asserted at a gate of the reset transistor 110 and a transfer signal TX is asserted at a gate of the transfer transistor 115. By simultaneously turning on the reset transistor 110 and the transfer transistor 115, the floating diffusion region 120 and the photodiode 105 are connected to the voltage reference 160, e.g. a power supply rail. This condition represents a reset state of the active pixel 100. That is, the voltage reference 160 provides a reset voltage for the active pixel 100.

Next, the transfer signal TX is negated at the gate of the transfer transistor 115, effectively turning off the transfer transistor 115 and the reset signal RST is negated at the gate of the reset transistor 110 to turn off the reset transistor 110, thus electrically isolating the photodiode 105 from the voltage reference 160.

At this stage, the photodiode 105 may be exposed to light, and will commence accumulation of charge accordingly. That is, an integration time is commenced by negating the transfer signal TX and permitting incident light to charge the photodiode 105. As photo-generated electrons accumulate in the photodiode 105, a voltage at the photodiode 105 decreases.

After the integration time the level of accumulated charge and hence the amount of radiation incident upon the photodiode 105 may be determined as follows.

The reset signal RST may be asserted at the gate of the reset transistor 110 to reset the floating diffusion region 120 to the voltage reference 160. In any event, at the end of the integration time, the reset signal RST is de-asserted to isolate the floating diffusion region 120.

Next, the transfer signal TX is temporarily asserted at a gate of the transfer transistor 115 to allow the accumulated charge on the photodiode 105 to be transferred to the floating diffusion region 120. That is, the photodiode 105 is temporarily coupled to the floating diffusion region 120, and hence to a gate of the source follower transistor 125. The charge transfer causes the voltage of the floating diffusion region 120 to drop from the voltage reference 160 to a second voltage indicative of an amount of charge accumulated on the photodiode 105 during the integration time.

Upon completion of the charge transfer, the row select transistor 130 is configured to couple the voltage at the source of the source follower transistor 125 to a further circuit, typically comprising a ramp-ADC (not shown).

FIG. 2a depicts a circuit diagram of a pixel 200 for an ambient light and/or color sensor according to an embodiment of the present disclosure. The pixel 200 is designed to exhibit characteristics not typically associated with a pinned photodiode that may be implemented in a typical CMOS image sensors, as described in more detail below.

The pixel 200 comprises a plurality of pinned photodiodes 205a, 205b, 205c, 205d, a reset transistor 210, a plurality of transfer transistors 215a, 215b, 215c, 215d, and a source follower transistor 225. In the circuit of FIG. 2a, each pinned photodiode 205a, 205b, 205c, 205d comprises a pinning layer above a radiation-sensitive structure, as described above with reference to FIG. 1.

The pixel 200 also comprises a floating diffusion region 220, which is represented as a capacitor in FIG. 2. In some embodiments, the floating diffusion region 220 may be configured to have a capacitance of 2.5 Femtofarads, or less.

Circuitry 230 is coupled to a gate of each transfer transistor 215a, 215b, 215c, 215d and the reset transistor 210. The circuitry 230 is configurable to select an integration time and to couple one or more of the plurality of pinned photodiodes 205a, 205b, 205c, 205d to the floating diffusion region in response to a sensed intensity of radiation incident on the pixel 200, as described in more detail below. The circuitry 230 may, for example, comprise logic, a state machine and/or a processor. The circuitry 230 may be programmable circuitry.

In contrast to the prior art pixel 100 of FIG. 1, in the pixel 200 according to an embodiment of the present disclosure, all of the plurality of transfer transistors 215a, 215b, 215c, 215d are coupled to a single floating diffusion region 220.

That is: a first pinned photodiode 205a is selectively coupled to the floating diffusion region 220 by control of a gate of a first transfer transistor 215a; a second pinned photodiode 205b is selectively coupled to the floating diffusion region 220 by control of a gate of a second transfer transistor 215b; a third pinned photodiode 205c is selectively coupled to the floating diffusion region 220 by control of a gate of a third transfer transistor 215c; and a fourth pinned photodiode 205d is selectively coupled to the floating diffusion region 220 by control of a gate of a fourth transfer transistor 215d.

In some embodiments, the single floating diffusion region 220 forms a node of each of the transfer transistors 215a, 215b, 215c, 215d, e.g. the single floating diffusion region 220 may effectively form the source or drain of each of the transfer transistors 215a, 215b, 215c, 215d. As such, each transfer transistor 215a, 215b, 215c, 215d is configurable to move a charge from a pinned photodiode 205a, 205b, 205c, 205d to the single floating diffusion region 220.

Similar to the prior art example of FIG. 1, the reset transistor 210 is coupled between a voltage reference 260 and the floating diffusion region 220 to reset the pixel 200, e.g., to discharge or charge the floating diffusion region 220 and the pinned photodiodes 205a, 205b, 205c, 205d to a reset voltage under control of the reset transistor 210. In the example embodiment of FIG. 2, the voltage reference 260 is a supply voltage, e.g. VDD. In some embodiments, the voltage reference 260 may be at a different voltage to the supply voltage VDD.

The source follower transistor 225 operates effectively as a voltage buffer, as is described above with regard to the source follower transistor 125 of FIG. 1, and therefore is not described in further detail.

An output of the source follower transistor 225, e.g. the source, is coupled to measurement circuitry, such as an ADC, to measure the effective voltage at the floating diffusion region 220 as described in more detail below with reference to FIGS. 3 and 4.

In use, the voltage at the floating diffusion region 220 corresponds to a charge stored at the floating diffusion region 220, and thus is indicative of an intensity of radiation which the pinned photodiodes 205a, 205b, 205c, 205d have been exposed to over an integration time.

A mode of operation of the pixel 200 is as follows.

In some embodiments, at an initial stage of operation, a reset signal is asserted at a gate of the reset transistor 210 by the circuitry 230 and a transfer signal is asserted at a gate of each transfer transistor 215a, 215b, 215c, 215d by the circuitry 230. By simultaneously turning on the reset transistor 210 and the transfer transistors 215a, 215b, 215c, 215d, the floating diffusion region 220 and the plurality of pinned photodiodes 205a, 205b, 205c, 205d are connected to the voltage reference 260, e.g. a power supply rail. This condition represents a reset state of the pixel 200. That is, the voltage reference 260 provides a reset voltage for the pixel 200.

Next, in some embodiments the transfer signal is negated at the gate of at least one of the transfer transistors 215a, 215b, 215c, 215d by the circuitry 230, effectively turning off the selected transfer transistor 215a, 215b, 215c, 215d.

At this stage, the pinned photodiodes 205a, 205b, 205c, 205d may be exposed to radiation, and will commence accumulation of charge accordingly. That is, an integration time is commenced by negating the transfer signal to at least one of the transfer transistors 215a, 215b, 215c, 215d thereby enabling incident radiation to charge the selected pinned photodiodes 205a, 205b, 205c, 205d, e.g. those pinned photodiodes having their associated transfer transistor 215a, 215b, 215c, 215d turned off as described above. As photo-generated electrons accumulate in the selected pinned photodiodes 205a, 205b, 205c, 205d, voltages at the selected pinned photodiodes 205a, 205b, 205c, 205d decreases.

After the integration time, the level of accumulated charge and hence an indication of the amount of radiation incident upon the selected pinned photodiodes 205a, 205b, 205c, 205d may be determined as follows.

In some embodiments, the reset signal may be asserted at the gate of the reset transistor 210 to reset the floating diffusion region 220 to the voltage defined by the voltage reference 260. In any event, at the end of the integration time, the reset signal is de-asserted to isolate the floating diffusion region 220. In some embodiments, this voltage may be read out as a reference for a Correlated Double Sampling (CDS) operation.

In some embodiments, the circuitry 230, which is coupled to the gate of each transfer transistor 215a, 215b, 215c, 215d, is configured to select which or how many, of the transfer transistors 215a, 215b, 215c, 215d are selected. For example, a selection may be made based upon a previous measurement of an intensity of radiation incident upon one or more of the pinned photodiodes 205a, 205b, 205c, 205d, as described below.

Next, the transfer signal is temporarily asserted by the circuitry 230 at a gate of the selected transfer transistors 215a, 215b, 215c, 215d to allow the accumulated charge on one or more of the pinned photodiodes 205a, 205b, 205c, 205d to be transferred to the floating diffusion region 220. That is, one or more of the pinned photodiodes 205a, 205b, 205c, 205d are temporarily coupled to the floating diffusion region 220, and hence to a gate of the source follower transistor 225. Charge transfer causes the voltage of the floating diffusion region 220 to drop from the voltage reference 260 to a second voltage indicative of an amount of charge accumulated on the one or more of the pinned photodiodes 205a, 205b, 205c, 205d during the integration time.

Upon completion of the charge transfer, further circuitry may be configured to measure a voltage at the source of the source follower transistor 225, as described in more detail below.

In contrast to the pixel 100 of FIG. 1, the embodiment of the disclosure shown as pixel 200 in FIG. 2 has four pinned photodiodes 205a, 205b, 205c, 205d coupled to a single floating diffusion region 220. The circuitry 230 may select which, and how many of the pinned photodiodes 205a, 205b, 205c, 205d are coupled to the floating diffusion region 220 for charge read-out. As such, operation of the pixel 200 can be optimized for a variety use cases. For example, in low incident radiation intensity conditions, the circuitry 230 may be configured to couple a relatively large amount, e.g. all four, of the pinned photodiodes 205a, 205b, 205c, 205d to the floating diffusion region 220. Conversely, in high incident radiation intensity conditions, the circuitry 230 may be configured to couple fewer pinned photodiodes 205a, 205b, 205c, 205d, e.g. one, two or three pinned photodiodes 205a, 205b, 205c, 205d to the floating diffusion region 220. That is, while the capacity of the floating diffusion region 220 to store a charge remains fixed, by selecting an appropriate amount of pinned photodiodes 205a, 205b, 205c, 205d in response to a previously sensed intensity of radiation incident on the pixel 200, an optimum usage of the floating diffusion region 220 may be made.

Similarly, the circuitry 230 may be configured to adjust the integration time, thereby also making optimum use of the floating diffusion region 220, and the storage capacity of the pinned photodiodes 205a, 205b, 205c, 205d. For example, the circuitry 230 may be configured to reduce the integration time in high incident radiation intensity conditions or increase the integration time in low incident radiation intensity conditions, to ensure the pinned photodiodes 205a, 205b, 205c, 205d operate within an optimal range. In some embodiments, the circuitry 230 may be configured to adapt the integration time in response to a previously sensed intensity of radiation incident on the pixel 200. For example, the circuitry 230 may be configured to avoid exceeding a charge storage capacity of each of the pinned photodiodes 205a, 205b, 205c, 205d.

FIG. 2b depicts a plan view of the pixel 200, according to an embodiment of the present disclosure. The pixel 200 comprises four pinned photodiodes 205a, 205b, 205c, 205d.

Also depicted in FIG. 2b are transfer gates 235a, 235b, 235c, 235d associated with each transfer transistor 215a, 215b, 215c, 215d respectively.

In a central area between the four pinned photodiodes 205a, 205b, 205c, 205d is the floating diffusion region 220. That is, the four pinned photodiodes 205a, 205b, 205c, 205d are arranged around the floating diffusion region 220.

Also depicted in FIG. 2b is a gate 240 associated with the reset transistor 210 and a gate 245 associated with the source-follower transistor 225.

For purposes of example only, a gate 250 associated with a dual conversion control transistor is also depicted. It will be understood that in some embodiments of the disclosure, the pixel 200 may comprise a dual conversion gain transistor included between the floating diffusion region 220 and the reset transistor 210. Such a dual conversion gain transistor may enable an additional capacitance to be selectively coupled to the floating diffusion region 220, thereby selectively increasing an effective charge storage capacity of the pixel 200, in certain conditions.

Notably, each pinned photodiode 205a, 205b, 205c, 205d comprises an active region having a relatively large area compared to an area of the floating diffusion region. In embodiments, a ratio of an active area of the plurality of pinned photodiodes to an area of the floating diffusion region is greater than 150.

In the example embodiment depicted in FIGS. 2a and 2b, each pinned photodiode 205a, 205b, 205c, 205d may have dimension in the region of approximately 12 μm×12 μm, thus having an active area in the region of 144 μm², minus any area for the transfer gate 235a, 235b, 235c, 235d and the floating diffusion region. The ‘active area’ may be defined as an area within each pinned photodiode that is diffused to create a PN or NP junction for converting photons into a current, and generally corresponds to the area of the photodiode as indicated in FIG. 2a, e.g. approximately 12 μm×12 μm minus a relatively small area around the transfer gate.

In embodiments of the disclosure, an active area of each pinned photodiode of the plurality of pinned photodiodes 205a, 205b, 205c, 205d is at least 25 μm².

Advantageously, such a large area may improve an overall sensitivity of the photodiodes.

The floating diffusion region 220 may have a relatively small area, such as in the region of 0.1 μm² or even less. A capacitance of the floating diffusion region 220, and hence an amount of charge that the floating diffusion region 220 may store, may be proportional to the area of the floating diffusion region 220. Thus, a charge storage capability of the floating diffusion region 220 may be relatively small for such large pinned photodiodes 205a, 205b, 205c, 205d, and hence accurate timing of integration times may be required to avoid saturation of the floating diffusion region 220, as described in more detail below.

By having a large active area of the plurality of pinned photodiodes 205a, 205b, 205c, 205d relative to an area of the floating diffusion region 220, an overall optical sensitivity and gain of the pinned photodiodes 205a, 205b, 205c, 205d may be improved. In particular, the relatively small area of the floating diffusion region 220 may result in a capacitance of the floating diffusion region 220 being low, such as 2.5 Femtofarads or less, hence increasing sensitivity levels of the pixel.

FIG. 3a depicts a portion of the pixel 200 of FIG. 2b, and FIGS. 3b to 3d correspond to cross sectional cuts across the lines marked on FIG. 3a as “A”, “B”, and “C” respectively. FIGS. 3a to 3d depict an example of a structure of a pixel 200 according to an embodiment of the disclosure.

FIG. 3b depicts a cross section of the portion of the pixel 200 in FIG. 3a along the line marked “A”. The line marked “A” extends through transfer gate 235c and through the pinned photodiode 205c.

The cross-section of FIG. 3b depicts the structure of the pixel 200 formed in an epitaxial-layer 305 (epi-layer) on a substrate 310. For simplicity of illustration, any other structures than may be formed in the substrate 310 or epi-layer 305, such as backside deep trench isolation (BIDI) structures, are not depicted.

A deep N-well 315 is formed in the P-type epitaxial layer 305 formed on the substrate 310. In some examples, one or more further N-type regions 320 may be formed in the deep N-well 315, such as regions of higher doping densities and/or shallower regions. It will be appreciated that in other examples falling within the scope of the disclosure, an N-type epitaxial layer may alternatively be implemented.

A P-type region 325 is formed in the deep N-well 315, thus defining a P-N junction and hence the active area of the photodiode 205c. A pinning layer 330 is formed from a shallow p+ implant above the P-N junction of the photodiode 205c.

Also depicted is the transfer gate 235c.

A deep P-well 335 is formed in the P-type epitaxial layer 305 and, in some embodiments, a further shallower P-well 340 may be formed in the deep P-well 335.

An N-type diffusion region formed in the P-well defines the floating diffusion region 220.

The photodiode 205c and the transfer gate 235c are designed to improve a charge transfer into the floating diffusion region 220, yet also reduce leakage which may contribute to a measureable dark current.

In some embodiments an additional diffusion region 345 for isolating the floating diffusion region 220 from the deep N-well 315 may be formed.

The pixel 200 is also optimized for color sensing applications. In embodiments of the disclosure a total thickness 350 of the pixel 200, including any epi-layer 305 and substrate 310 may for example, be in a range of around 2 to 6 μm, depending upon process capability

The total thickness of the pixel may be increased by increasing a thickness of the epi-layer. For example, in some embodiments, the epi—layer may be 2.5 μm or greater.

Advantageously, by increasing the total thickness a temperature coefficient of red response may be reduced. While a total thickness, e.g. the epi-thickness, may not be particularly important for pixels for regular CMOS image sensors, such an increased thickness makes the disclosed pixel particularly suited to color sensing applications by improving a red-response. That is, in some examples, color sensors and/or ambient light sensors implemented using the disclosed pixel may sense color by determining a ratio of sensed red radiation to sensed green radiation, and thus for accurate color sensing a stability of sensed color across an operating temperature range is advantageous.

FIG. 3c depicts a cross section of the portion of the pixel 200 in FIG. 3a along the line marked “B”. For simplicity of illustration, the epi-layer 305 and the substrate 310 are omitted from FIG. 3c.

The gate 240 associated with the reset transistor 210 and the gate 250 associated with a dual conversion control transistor are depicted. As described above, in some embodiment the dual conversion control transistor may not be implemented.

Also depicted in FIG. 3c is a shallow P-well 355 formed in a deep P-well 360. The gate 240 associated with the reset transistor 210 and the gate 250 associated with a dual conversion control transistor are formed over the shallow P-well. Shallow trench isolation from the active region of the pinned photodiode is implemented with first trench 365 and second trench 370.

In use, a voltage applied to the gate 240 associated with the reset transistor 210 may reset the floating diffusion region 220 to a reference voltage, e.g. VDD.

In example embodiments, a threshold voltage of the reset transistor 210 may be configured to be at greater than 0.1 volts, e.g. at an ambient temperature, e.g. by selecting any of particular sizes, shapes, doping concentrations and/or dopants to form the reset transistor 210.

That is, a threshold of the reset transistor 210 may be relatively high when compared to a pixel implemented in a regular CMOS image sensor.

Advantageously, a threshold of greater than 0.1 volts enables a reduction in leakage currents, thereby reducing a dark count. The reset transistor 210 may be sized to minimize any parasitic capacitances.

A size of the reset transistor 210 may be minimized to provide a lower-leakage transistor compared to that of a regular CMOS image sensor. Leakage from the reset transistor 210 may be at least one decade lower in magnitude relative to leakage from a reset transistor 210 in a pixel of a regular CMOS image sensor.

FIG. 3d depicts a cross section of the portion of the pixel 200 in FIG. 3a along a line marked “C”. For simplicity of illustration, the epi-layer 305 and the substrate 310 are omitted from FIG. 3c.

A gate 370 associated with source-follower transistor 225 is depicted. The gate 370 is formed over a shallow P-well 375, which is formed in a deep P-well 380. A channel region 395 below the gate 370 is isolated from the active area of the photodiodes using shallow-trench isolation by third trench 385 and fourth trench 390.

The source-follower transistor 225 is designed as a highly sensitive node, and a gate capacitance of the source-follower transistor 225 is minimized to maximize an optical sensitivity of the pixel 200.

In some embodiment, the source-follower transistor 225 is formed having a gate width of 0.4 μm or less.

FIG. 4 depicts a representation of a plan view of a pixel 400 according to an embodiment of the disclosure. The pixel comprises four pinned photodiodes 405a, 405b, 405c, 405d arranged around a floating diffusion region 420. An example position of the floating diffusion region 420 relative to the four pinned photodiodes 405a, 405b, 405c, 405d is denoted in dashed line for illustrative purposes.

A plurality of signals, denoted “Signal xn” and “Signal yn” are provided in one or more metal layers formed over the pixel 400. The signals may, for example, be for controlling each transfer gate and/or reset transistor of the pixel 400.

In order to shield each signal and minimize the effects of interference, each signal is flanked by one or more voltage references. The voltage reference may be ground level, e.g. zero volts, and/or a power supply voltage, e.g. VDD. In the example of FIG. 4, the voltage references are denoted “VDD” and “GND”.

In the example embodiment, to minimize any interference, such as crosstalk, the signals, and/or any metal lines for shielding such signals, are routed at a minimum distance 410, 415 of at least 1 μm from the floating diffusion 420.

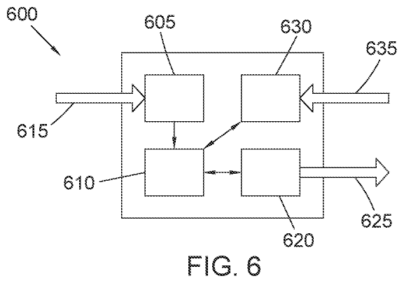

FIG. 500 depicts a diagram of a sensor 500 comprising a pixel according to an embodiment of the disclosure.

The sensor 500 comprises a pixel 505. The pixel 505 corresponds to the pixel 200 of FIGS. 2A and 2B. The pixel 505 comprises four pinned photodiodes 510a, 510b, 510c, 510d. Although in FIG. 5 each of the four pinned photodiodes 510a, 510b, 510c, 510d depict a floating diffusion region, it will be appreciated that this is shown for illustrative purposes only, and the pixel 505 comprises only a single shared floating diffusion region 520. The single shared floating diffusion region 520 is shared between the four pinned photodiodes 510a, 510b, 510c, 510d, e.g. as depicted by the capacitor 220 in the pixel 200 of FIG. 2A.

The circuit 500 also comprises a sample and hold circuit 515. The sample and hold circuit 515 is a correlated double sampling circuit, enabling differencing of samples from the pixel(s) 505 to be taken before and after an integration time to reduce the effects of noise in the system.

Also depicted in the sample and hold circuit 515 is a current source 535 for biasing the source follower of the pixel 505.

The circuit 500 may be configured to accumulate and/or average a signal from each pixel of a plurality of pixels prior to analog-to-digital conversion. For example, in the circuit 500 of FIG. 5 only one pixel 505 is depicted. However, a plurality of pixels 505 may be coupled to the sample and hold circuitry 515. For example, and as denoted by “<6:1>” in FIG. 5, in the described embodiment six pixels 505 are coupled to the sample and hold circuit 515. For example, an output of the source-follower of six pixels 505 may be coupled to a column line, wherein the column line is coupled to the sample and hold circuitry.

The circuit 500 also comprises an output buffer 525 for maintaining a voltage level at an output of the circuit 500 prior to conversion by an ADC 530.

FIG. 6 depicts an electronic device 600 according to an embodiment of the disclosure. The electronic device 600 may be a smartphone, tablet device, smart-watch, a laptop device, a personal computer, a camera, or a television. The electronic device 600 may be a communications device, e.g. a device configured to receive and/or transmit a signal.

The example electronic device 600 comprises a sensor 605 for ambient light and/or color sensing. The sensor 605 is a sensor as described above with reference to FIG. 5. The sensor 605 is configured to be exposed to incident radiation 615. One or more optical components (not shown), such as lenses, diffusers, polarizers, or the like may be provided between the sensor 605 and the source of incident radiation 615. In some embodiments, the sensor may be configured for backside-illumination.

Also depicted in FIG. 6 is a processor 610 coupled to the sensor 605. The processor may be configured to control the sensor and/or receive data from the sensor 605. The processor 610 may be configured to perform digital signal processing of data or a signal received from the sensor 605.

Although only a single processor 610 is depicted, it will be understood that the processor 610 may represent a plurality of processors.

In some embodiments, the processor 610 and the sensor 605 may be implemented as a monolithic device, e.g., a single integrated circuit device. In other embodiments, the sensor 605 may be provided as a separate device.

Also depicted in FIG. 6 is a display 620 such as an LED display configured to emit radiation 625, e.g. display an image. The processor 610 may be configured to control the display 620 to display an image.

In some embodiments, the processor 610 may be configured to adapt an image displayed by the display 620 in response to an ambient radiation 615 sensed by the sensor 605. For example, the processor 610 may be configured to brighten an image displayed by the display 620 in response to sensing a relatively high intensity of incident ambient radiation 615.

In some embodiments, the processor 610 may be configured to adapt an image displayed by the display 620 in response to a color of radiation 615 sensed by the sensor 605. For example, the processor 610 may be configured to identify or classify a light source based on a detected color of radiation 615 incident upon the sensor 605. In an example, the processor 610 may be configured to identify or classify a light source as a fluorescent, LED or incandescent light source, or the like.

The example device also comprises a camera 630 configured to capture an image from incident radiation 635, and controlled by the processor 610. In one example use case, the processor 610 may be configured to perform automatic white balancing of an image captured by the camera 630 in response to a color of radiation 615 sensed by the sensor 605.

In some embodiments, the sensor 605 mat be disposed rearward of a radiation-emitting surface of the display 620 and configured and receive radiation propagating through the LED display. The display may be an organic LED display. As such, the sensor 605 may be implemented in a Behind-Organic-LED (BOLED) display application.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

REFERENCE NUMERALS

| | |
|---|---|
| 100 | active pixel |
| 105 | photodiode |
| 110 | reset transistor |
| 115 | transfer transistor |
| 120 | floating diffusion region |
| 125 | source follower transistor |
| 130 | row select transistor |
| 150 | pinning layer |
| 160 | voltage reference |
| 200 | pixel |
| 205a-d | pinned photodiode |
| 210 | reset transistor |
| 215a-d | transfer transistor |
| 220 | floating diffusion region |
| 225 | source-follower transistor |
| 230 | circuitry |
| 235a-d | transfer gates |
| 240 | gate |
| 245 | gate |
| 250 | gate |
| 260 | voltage reference |
| 305 | epi-layer |
| 310 | substrate |
| 315 | deep N-well |
| 320 | N-type region |
| 325 | P-type region |
| 330 | pinning layer |
| 335 | deep P-well |
| 340 | shallow P-well |
| 345 | diffusion region |
| 350 | total thickness |
| 355 | shallow P-well |
| 360 | deep P-well |
| 365 | first trench |
| 370 | second trench |
| 375 | shallow P-well |
| 380 | deep P-well |
| 385 | third trench |
| 390 | fourth trench |
| 395 | channel region |
| 400 | pixel |
| 405a-d | photodiodes |
| 410 | minimum distance |
| 415 | minimum distance |
| 420 | floating diffusion region |
| 500 | sensor |
| 505 | pixel |
| 510a-d | pinned photodiodes |
| 515 | sample and hold circuit |
| 520 | floating diffusion region |
| 525 | output buffer |
| 530 | ADC |
| 535 | current source |
| 600 | electronic device |
| 605 | sensor |
| 610 | processor |
| 615 | incident radiation |
| 620 | display |
| 625 | radiation |
| 630 | camera |
| 635 | incident radiation |

1. A pixel for an ambient light and/or color sensor comprising:
a plurality of pinned photodiodes; and
a floating diffusion region;
wherein a ratio of an active area of the plurality of pinned photodiodes to an area of the floating diffusion region is greater than 150.

2. The pixel of claim 1, wherein an active area of each pinned photodiode of the plurality of pinned photodiodes is at least 25 μm².

3. The pixel of claim 1, wherein the floating diffusion region is configured to have a capacitance of 2.5 Femtofarads or less.

4. The pixel of claim 1, wherein the pixel is an active pixel comprising:
a reset transistor configured to reset the floating diffusion region to a reference voltage;
a plurality of transfer gates, each transfer gate configurable to transfer a charge from one of the plurality of pinned photodiodes to the floating diffusion region;
a read-out transistor configured as a source-follower transistor for sampling a voltage at the floating diffusion region.

5. The pixel of claim 4, wherein a threshold voltage of the reset transistor is configured to be greater than 0.1 volts.

6. The pixel of claim 4, wherein the read-out transistor is formed to with a width of less than 1 um.

7. The pixel of claim 4, wherein signals for controlling each transfer gate and/or reset transistor and/or any metal lines for shielding such signals are routed at a minimum distance of at least 1 μm from the floating diffusion region.

8. The pixel, of claim 1, comprising four pinned photodiodes arranged around the floating diffusion region.

9. A sensor for color or ambient light sensing, comprising at least one pixel according to claim 1.

10. The sensor of claim 9 comprising circuitry configurable to selectively couple each pinned photodiode to the floating diffusion region.

11. The sensor of claim 10, wherein the circuitry is configurable to select an integration time and to couple one or more of the plurality of pinned photodiodes to the floating diffusion region in response to a sensed intensity of radiation incident on the pixel.

12. The sensor claim 9, configured to exhibit a resolution of at least 12 bits and/or a dynamic range of at least 22 bits.

13. An electronic device comprising the sensor of claim 9, wherein the sensor is configured for backside-illumination.

14. The electronic device of claim 13, comprising an LED display, wherein the sensor is disposed rearward of a radiation-emitting surface of the LED display and configured and receive radiation propagating through the LED display.
